(19) United States
(12) Patent Application Publication
(10) Pub. No.: US 2026/0002986 A1
(43) Pub. Date: Jan. 1, 2026

(54) DETECTION OF STRUCTURAL DEFECTS IN AN INTEGRATED CIRCUIT

(71) Applicant: STMicroelectronics International N.V., Geneva (CH)

(72) Inventor: Laurent Lopez, Peynier (FR)

(21) Appl. No.: 19/239,419

(22) Filed: Jun. 16, 2025

(30) Foreign Application Priority Data
Jun. 26, 2024 (FR) 2406877

(51) Int. Cl. G01R 31/28; H01L 23/10

(52) U.S. Cl. CPC G01R 31/2884; G01R 31/2843; H01L 23/10

(57) ABSTRACT

The integrated circuit is equipped with an annular wall including, in a first part, an alternation of conductive stacks containing metal tracks distributed over several metal levels and having an alternately reversed trapezoidal longitudinal section, all these tracks forming together at least one electrically conductive path having at least one staircase portion in a second part of the wall. Defect-detection circuit are located in the integrated circuit and connected to semiconductor zones buried in the substrate under the second part of the wall and connected to the two ends of the at least one electrically conductive path.

### CROSS-REFERENCE TO RELATED APPLICATIONS

This application claims priority to French Application No. FR 2406877, filed on Jun. 26, 2024, which application is hereby incorporated herein by reference.

### TECHNICAL FIELD

Embodiments and implementations relate to integrated circuits, in particular the detection of structural defects in these integrated circuits.

### BACKGROUND

Integrated circuits are manufactured simultaneously on locations on a silicon wafer separated by cutting lines.

Then, once manufactured, the integrated circuits are individualized by cutting the wafer, typically by sawing, along the cutting lines.

An integrated circuit conventionally includes a part known to a person skilled in the art by the English acronym “FEOL” (“Front End Of Line” or more simply “front end”) including the various components, such as transistors, implemented in and on the semiconductor substrate of the integrated circuit, and a part known to a person skilled in the art by the English acronym “BEOL” (“Back End Of Line” or more simply “back end”) including a network of metal tracks and vias embedded in a dielectric material and implementing in particular an interconnection between the components of the integrated circuit.

An integrated circuit also generally includes a sealing ring located at the periphery of the integrated circuit.

A sealing ring conventionally comprises metal tracks interconnected by vias, the whole embedded in a dielectric material. Furthermore, a passivation layer is located at the top of the sealing ring and provides, in combination with the sealing ring, protection against the penetration of moisture inside the integrated circuit, which would impact the reliability of the integrated circuit.

During the operation of sawing the wafer mentioned above, cracks and/or a phenomenon of delamination (i.e. a decohesion of the layers) may occur in the BEOL part, in particular at the periphery of the integrated circuit.

These structural defects may particular affect the sealing ring, which is detrimental.

There are already structures making it possible to detect structural defects. However, such structures do not make it possible to detect certain configurations of cracks and/or certain delamination locations.

There is therefore a need to remedy this drawback.

### SUMMARY

According to one embodiment, a novel structure is proposed making it possible to greatly improve the detection of such structural defects by increasing the detectable locations of cracks and delamination.

According to one aspect, an integrated circuit is proposed, comprising a semiconductor substrate, and an annular wall, located on and at the periphery of the semiconductor substrate.

This annular wall includes, in a first part, at least one first conductive stack and at least one second conductive stack, preferably an alternation of first and second conductive stacks, adapted to be mutually electrically connected.

Each first conductive stack includes a stack of first electrically conductive tracks (for example metal tracks distributed over N, for example 5, levels of metal of the integrated circuit) separated by an electrically insulating material and arranged in a first pattern having a longitudinal section of the trapezoidal type.

Each second conductive stack includes a stack of second electrically conductive tracks (for example metal tracks distributed over N−1 levels of metal and a doped semiconductor layer covering the semiconductor substrate) separated by the electrically insulating material and arranged in a first pattern having a longitudinal section of the trapezoidal type reversed with respect to the longitudinal section of the first pattern.

All the first and second electrically conductive tracks forming together at least one electrically conductive path having two ends in a second part of the wall.

Each end of each electrically conductive path is adapted to be electrically connected to a semiconductor zone buried in the substrate under the second part of the wall.

At least one electrically conductive path includes a staircase portion in said second part of the wall.

The integrated circuit also includes detection circuit adapted to be connected to said semiconductor zones and configured to detect at least one type of structural defect in the integrated circuit, for example a crack or a delamination, by detecting at least one electrical interruption of at least one electrically conductive path of the annular wall.

Combining conductive stacks with a trapezoidal longitudinal section alternately reversed and non-reversed and one or more staircase portions makes it possible to increase the number of detectable locations of defects.

According to one embodiment, the electrically conductive path comprises, in the second part of the wall, metal tracks located on successive metal levels of the integrated circuit.

According to one embodiment, the staircase portion (stepped portion) comprises a metal track of one metal level that is coupled to a metal trace of an adjacent metal level, that is, a directly higher or lower metal level, by at least one conductive via. The metal track is laterally offset with respect to the adjacent metal track.

This lateral offset corresponds to a shift in a horizontal plane parallel to the semiconductor substrate. It results in a geometric shape similar to a staircase or a succession of steps. In other words, a metal track A of a metal level n, which is coupled to an adjacent metal track B of metal level n−1 or n+1 by at least one conductive via, is laterally offset with respect to the latter. Thus, the metal track A comprises a portion that is not vertically aligned with the adjacent metal track B, that is, a portion that is not located directly above or below to the latter.

According to one embodiment, in said staircase portion, two adjacent metal tracks that are laterally offset from one another have a mutual overlap region with a length ranging from 1 μm to 10 μm.

According to one embodiment, in the staircase portion, a metal track A of a metal level n is coupled to an upper metal track B of an adjacent upper metal level n+1 by at least one upper conductive via AB, and is coupled to a lower metal track C of an adjacent lower metal level n−1 by a lower conductive via AC. The metal track A may be laterally offset with respect to the upper metal track B and/or the lower metal track C. The upper conductive via AB and the lower conductive via AC may then be laterally offset from each other, that is, they may not be located directly vertically or perpendicularly to one another.

According to one embodiment, a metal track A of a staircase portion, laterally offset with respect to a metal track B or C of an adjacent metal level to which it is coupled by at least one conductive via, is partially vertically superposed on another metal track of the same adjacent metal level.

According to one embodiment, the two metal tracks partially vertically superposed on one another may belong to different staircase portions.

According to one embodiment, the first electrically conductive tracks comprise N first metal tracks respectively located on the N first metal levels of the integrated circuit, N being greater than or equal to 2, and the second electrically conductive tracks comprise an electrically conductive layer on the top surface of the substrate and N−1 second metal tracks respectively located on the N−1 first metal levels.

According to one embodiment, all the first and second electrically conductive tracks form together N electrically conductive paths respectively located on the N first metal levels of the integrated circuit, and the integrated circuit comprises 2N buried semiconductor zones.

These N electrically conductive paths are thus here connected separately to the detection circuit.

According to another possible embodiment making it possible to reduce the number of buried semiconductor zones, all the first and second electrically conductive tracks form together N electrically conductive paths respectively located on the N first metal levels of the integrated circuit, the N electrically conductive tracks having respectively N first ends respectively connected to N distinct buried semiconductor zones and N second ends all connected to one and the same second buried zone.

Thus in this embodiment the N electrically conductive tracks are connected in a star.

According to an embodiment making it possible to further reduce the number of buried semiconductor zones, all the first and second electrically conductive tracks form together a single electrically conductive path extending over the N first metal levels of the integrated circuit, the two ends of the path being connected to two buried semiconductor zones.

In other words, the N electrically conductive paths are here connected in series so as to form only a single electrically conductive path.

The integrated circuit advantageously generally comprises a sealing ring located on and at the periphery of the semiconductor substrate.

This sealing ring can contain said annular wall.

In a variant, said annular wall can bear on one or other of the sides of the sealing ring.

In a variant, the integrated circuit can include two annular walls bearing respectively on the two sides of the sealing ring.

According to another aspect, a method is proposed for detecting at least one type of structural defect in an integrated circuit, for example a crack and/or a delamination, wherein the integrated circuit is equipped with an annular wall, located on and at the periphery of the semiconductor substrate of the integrated circuit, and including in a first part an alternation of first and second conductive stacks mutually electrically connected, each first conductive stack including a stack of first electrically conductive tracks separated by an electrically insulating material and arranged in a first pattern having a longitudinal section of the trapezoidal type, and each second conductive stack including a stack of second electrically conductive tracks separated by the electrically insulating material and arranged in a second pattern having a longitudinal section of the trapezoidal type reversed with respect to the first pattern, all the first and second electrically conductive tracks forming together at least one electrically conductive path having, in a second part of the wall, two ends, each end of each electrically conductive path being electrically connected to a semiconductor zone buried in the substrate under the second part of the wall, at least one electrically conductive path including a staircase portion in said second part of the wall, a potential difference is applied between the two ends of said at least one electrically conductive path, and an absence of current circulating in said at least one electrically conductive path is detected.

### BRIEF DESCRIPTION OF THE DRAWINGS

Other advantages and features of the invention will appear upon examining the detailed description of non-limiting implementations and embodiments, and from the appended drawings, wherein:

FIG. 1 illustrates a plan view of an integrated circuit in accordance with an embodiment;

FIG. 2 illustrates a plan view of an integrated circuit comprising a wall located on the external side of the sealing ring in accordance with an embodiment;

FIG. 3 illustrates a plan view of an integrated circuit comprising a wall located on the internal side of the sealing ring in accordance with an embodiment;

FIG. 4 illustrates a plan view of an integrated circuit comprising a first wall located on the external side of the sealing ring and a second wall located on the internal side of the sealing ring in accordance with an embodiment;

FIG. 5 illustrates a longitudinal section of the structure of the wall in accordance with an embodiment;

FIG. 6 illustrates a longitudinal section of the structure of the wall with semiconductor zones buried in the substrate under the part of the wall in accordance with an embodiment;

FIG. 7 illustrates a longitudinal section of the structure of the wall with reduced number of buried zones in accordance with an embodiment;

FIG. 8 illustrates a longitudinal section of the structure of the wall with reduced number of buried zones by producing a single electrically conductive path in accordance with an embodiment; and

FIG. 9 illustrates a method of detecting defects in the IC in accordance with an embodiment.

### DETAILED DESCRIPTION OF ILLUSTRATIVE EMBODIMENTS

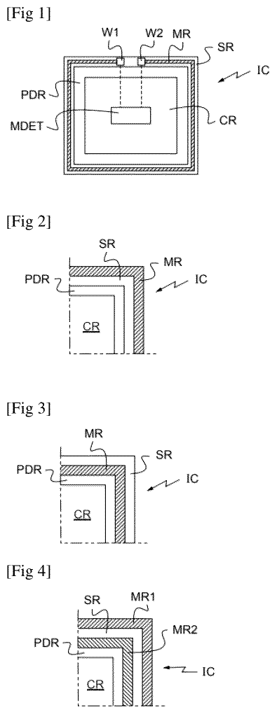

On FIG. 1 the reference IC designates an integrated circuit shown here highly schematically in plan view.

The integrated circuit comprises a core CR typically including one or more components, for example but not limited to a microcontroller, surrounded by a ring of contact pads PDR, itself surrounded in this embodiment by a sealing ring SR incorporating here an annular wall MR.

The sealing ring SR and the annular wall MR are located on and at the periphery of the semiconductor substrate of the integrated circuit.

This annular wall, examples of structures of which will be detailed hereinafter, includes, as will be seen hereinafter, at least one electrically conductive path, the two ends of which are connected to two semiconductor zones W1 and W2, for example wells of n conductivity type, buried under the annular wall MR in the semiconductor substrate, for example of the p conductivity type, of the integrated circuit.

The core CR of the integrated circuit includes detection circuit MDET connected to said semiconductor zones W1, W2, and configured to detect at least one type of structural defect in the integrated circuit, for example a crack and/or a delamination, by detecting at least one electrical interruption of at least one electrically conductive path of the annular wall.

In this regard, as will be seen in more detail hereinafter, the detection circuit MDET, with a conventional structure, are configured to apply a potential difference between the two semiconductor zones W1, W2 and therefore between the two ends of the electrically conductive path, and to detect the presence or absence of a current.

In a variant, as illustrated schematically on FIG. 2, the wall MR can be located outside the sealing ring SR and bear on the external side of the sealing ring.

In a variant, as illustrated schematically on FIG. 3, the wall MR can be located inside the sealing ring SR and bear on the internal side of the sealing ring, i.e., on the same side as the core CR.

In a variant, as illustrated schematically on FIG. 4, the integrated circuit can include a first wall MR1 located outside the sealing ring SR and bearing on the external side of the sealing ring, and a second wall MR2 located inside the sealing ring SR and bearing on the internal side of the sealing ring.

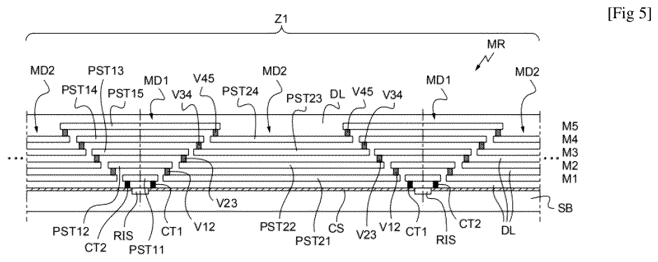

Reference is now made more particularly to FIGS. 5 to 8 to describe example of a structure of the wall MR.

These FIGS. 5 to 8 are schematic longitudinal sections.

As illustrated on FIG. 5, the annular wall MR, which is located in the BEOL part of the integrated circuit, includes, in a first part Z1, an alternation of first conductive stacks MD1 and second conductive stacks MD2 mutually electrically connected.

Each first conductive stack MD1 includes a stack of first electrically conductive tracks distributed over N levels of metal of the integrated circuit, and separated by an electrically insulating material, typically a dielectric material DL.

More precisely, here, N is equal to 5 and the first electrically conductive tracks include five first metal tracks PST11, PST12, PST13, PST14 and PST15 respectively located on the five first metal levels M1, M2, M3, M4 and M5 of the integrated circuit.

These metal tracks are arranged in a first pattern having a longitudinal section of the trapezoidal type, the track PST15 forming the large base of the trapezium and the track PST11 forming the small base of the trapezium.

Each second conductive stack MD2 includes a stack of second electrically conductive tracks distributed over N−1 levels of metal and an electrically conductive layer CS, for example a layer of metal silicide, separated by the electrically insulating material DL.

More precisely, the second electrically conductive tracks include four metal tracks PST21, PST22, PST23 and PST24 respectively located on the four first metal levels M1, M2, M3 and M4.

These four metal tracks and the layer CS are arranged in a second pattern having a longitudinal section of the trapezoidal type reversed with respect to the longitudinal section of the first pattern.

More precisely, in the second pattern, it is this time the layer CS that forms the large base of the trapezium and it is the track PST24 that forms the small base of the trapezium.

The electrical connection between a first conductive stack MD1 and a second conductive stack MD2 is made by means of vias and contacts between the first electrically conductive tracks and the second electrically conductive tracks.

More precisely, the vias V45 electrically connect the second track PST24 of a second conductive stack MD2 to the first track PST15 of each first conductive stack MD1 framing the second conductive stack MD2.

The vias V34 electrically connect the second track PST23 of a second conductive stack MD2 to the first track PST14 of each first conductive stack MD1 framing the second conductive stack MD2.

The vias V23 electrically connect the second track PST22 of a second conductive stack MD2 to the first track PST13 of each first conductive stack MD1 framing the second conductive stack MD2.

The vias V12 electrically connect the second track PST21 of a second conductive stack MD2 to the first track PST12 of each first conductive stack MD1 framing the second conductive stack MD2.

The contacts CT1 electrically connect the layer CS of a second conductive stack MD2 to the first track PST11 of each first conductive stack MD1 framing the second conductive stack MD2.

The contacts CT2 electrically connect the first track PST11 of a first conductive stack MD1 to the layer CS of each second conductive stack MD2 adjacent to the first conductive stack MD1.

Other vias electrically connect respectively the first tracks PST12-PST15 of a first conductive stack MD1 to the second tracks PST21 of each second conductive stack MD2 adjacent to the first conductive stack MD1.

Finally, an isolating region RIS, for example a shallow trench, located in the semiconductor substrate SUB of the integrated circuit between the contacts CT1 and CT2, interrupts the electrical continuity of the layer CS.

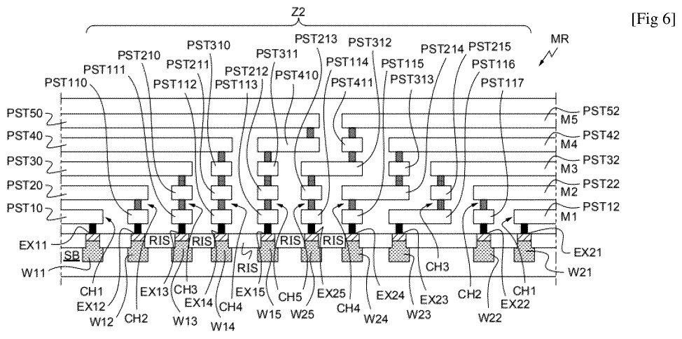

The wall MR also includes a second part Z2 with various examples of structures respectively illustrated on FIGS. 6 to 8.

In the example of FIG. 6, the integrated circuit includes ten semiconductor zones W11-W15 and W21-W25 buried in the substrate SB under the second part Z2 of the wall.

These semiconductor zones are for example n-doped wells, the substrate being of p-type conductivity.

### Formation of an Electrically Conductive Path CH5

For forming this path CH5, the wall also includes, at the metal level M5, two metal tracks PST50 and PST52 that respectively extend on each side the alternation of the first and second conductive stacks MD1 and MD2.

The track PST50 is connected to the semiconductor zone W15 by means of the metal tracks PST410, PST311, PST212, PST113 respectively located at the metal levels M4, M3, M2 and M1, and by means of vias and a contact.

The track PST52 is connected to the semiconductor zone W25 by means of the metal tracks PST411, PST312, PST213, PST114 respectively located at the metal levels M4, M3, M2 and M1, and by means of vias and a contact.

The tracks PST15 and PST24 of the conductive stacks MD1 and MD2 form, with the tracks PST50, PST52, PST410, PST311, PST212, PST113, PST411, PST312, PST213, PST114 and the corresponding vias and contacts, the electrically conductive path CH5, the two ends EX15 and EX25 of which are connected to the two buried zones W15 and W25.

Moreover, as can be seen on the figure, this path CH5 includes a first staircase portion formed by the track PST410 and the stack of tracks PST311, PST212 and PST113, and a second staircase portion formed by the track PST411, the track PST312 and the stack of tracks PST213 and PST114.

Thus, in the first staircase portion, the metal track PST410 is laterally offset, in a horizontal plane parallel to that of the substrate, with respect to the adjacent track PST311. In other words, the metal track PST410 extends further, in a horizontal plane, than the track PST311: a portion of the track PST410 is not vertically aligned (i.e., not directly above) the track PST311. Here, the upper conductive via coupling the track PST410 to the track PST50 is not vertically aligned with the lower conductive via coupling the track PST410 to the track PST311. Therefore, if a vertical crack were to appear in a region located between these two conductive vias, it could be detected.

Furthermore, in the second staircase portion, the metal track PST312 is laterally offset, in a horizontal plane, with respect to the adjacent upper track PST411, but also with respect to the adjacent lower track PST213. In other words, the metal track PST312 extends further, in the horizontal plane, than the adjacent upper track PST411, in this case towards the left. In addition, it also extends further, in a horizontal plane, than the adjacent lower track PST213. Here, the upper conductive via coupling the track PST312 to the track PST411 is not vertically aligned with the lower conductive via coupling the track PST312 to the track PST213. Therefore, if a vertical crack were to appear in a region located between these two conductive vias, it could be detected.

In addition, there is here a partial vertical superposition of the first staircase portion with the second staircase portion. In other words, the metal track PST410 is at least partially vertically superposed on the metal track PST312. A portion of the track PST410 is therefore vertically aligned with a portion of the track PST312. Furthermore, the conductive via coupling the tracks PST50 and PST410 is here vertically aligned with the conductive via coupling the tracks PST312 and PST213. This arrangement, in which two staircase portions are partially vertically superposed, makes it possible to detect vertical cracks that may be present between these two parts of the electrical path CH5.

### Formation of an Electrically Conductive Path CH4

For forming this path CH4, the wall also includes, at the metal level M4, two metal tracks PST40 and PST42 that respectively extend on each side the alternation of the first and second conductive stacks MD1 and MD2.

The track PST40 is connected to the semiconductor zone W14 by means of the metal tracks PST310, PST211, PST112, respectively located at the metal levels M3, M2 and M1, and by means of vias and a contact.

The track PST42 is connected to the semiconductor zone W24 by means of the metal tracks PST313, PST214, PST115 respectively located at the metal levels M3, M2 and M1, and by means of vias and a contact.

The tracks PST14 and PST23 of the conductive stacks MD1 and MD2 form, with the tracks PST 40, PST42, PST310, PST211, PST112, PST313, PST214, PST115 and the corresponding vias and contacts, the electrically conductive path CH4, the two ends EX14 and EX24 of which are connected to the two buried zones W14 and W24.

Moreover, as can be seen on the figure, this path CH4 includes a staircase portion formed by the tracks PST313, PST214 and PST115.

Thus, the metal track PST214 is laterally offset, in a horizontal plane, with respect to the adjacent upper track PST313, but also with respect to the adjacent lower track PST115. Furthermore, the upper conductive via coupling the track PST313 to the track PST214 is not vertically aligned with the lower conductive via coupling the track PST214 to the track PST115. Therefore, if a vertical crack were to appear in a region located between these two conductive vias, it could be detected.

In addition, there is a partial vertical superposition of the staircase portion PST313/PST214/PST115 with the staircase portion PST411/PST312/PST213. This arrangement, in which two staircase portions are partially vertically superposed, enables the detection of vertical cracks that may be present between these two parts of the electrical paths CH5 and CH4.

### Formation of an Electrically Conductive Path CH3

For forming this path CH3, the wall also includes, at the metal level M3, two metal tracks PST30 and PST32 that respectively extend on each side the alternation of the first and second conductive stacks MD1 and MD2.

The track PST30 is connected to the semiconductor zone W13 by means of the metal tracks PST210, PST111 respectively located at the metal levels M2 and M1, and by means of vias and a contact.

The track PST32 is connected to the semiconductor zone W23 by means of the metal tracks PST215, PST116 respectively located at the metal levels M2 and M1, and by means of vias and a contact.

The tracks PST13 and PST22 of the conductive stacks MD1 and MD2 form, with the tracks PST30, PST32, PST210, PST111, PST215, PST116 and the corresponding vias and contacts, the electrically conductive path CH3, the two ends EX13 and EX23 of which are connected to the two buried zones W13 and W23.

Moreover, as can be seen on the figure, this path CH3 includes a staircase portion formed by the tracks PST215 and PST116.

Thus, the metal track PST116 is laterally offset, in a horizontal plane, with respect to the adjacent upper track PST215. Furthermore, the upper conductive via coupling the track PST116 to the track PST215 is not vertically aligned with the lower conductive via coupling the track PST116 to the well W23. Therefore, if a vertical crack were to appear in a region located between these two conductive vias, it could be detected.

In addition, there is a partial vertical superposition of the staircase portion PST215/PST116 with the staircase portion PST313/PST214/PST115. This arrangement, in which two staircase portions are partially vertically superposed, enables the detection of vertical cracks that may be present between these two parts of the electrical paths CH4 and CH3

### Formation of an Electrically Conductive Path CH2

For forming this path CH2, the wall also includes, at the metal level M2, two metal tracks PST20 and PST22 that respectively extend on each side the alternation of the first and second conductive stacks MD1 and MD2.

The track PST20 is connected to the semiconductor zone W12 by means of the metal track PST110 located at the metal level M1, and by means of a via and a contact.

The track PST22 is connected to the semiconductor zone W22 by means of the metal track PST117 located at the metal level M1, and by means of a via and a contact.

The tracks PST12 and PST21 of the conductive stacks MD1 and MD2 form, with the tracks PST20, PST22, PST110, PST117 and the corresponding vias and contacts, the electrically conductive path CH2, the two ends EX12 and EX22 of which are connected to the two buried zones W12 and W22.

### Formation of an Electrically Conductive Path CH1

For forming this path CH1, the wall also includes, at the metal level M1, two metal tracks PST10 and PST12 that respectively extend on each side the alternation of the first and second conductive stacks MD1 and MD2.

The track PST10 is connected to the semiconductor zone W11 by means of a contact.

The track PST12 is connected to the semiconductor zone W12 by means of a contact.

The tracks PST11 and the semiconductor layer CS of the conductive stacks MD1 and MD2 form, with the tracks PST10, PST12 and the corresponding vias and contacts, the electrically conductive path CH1, the two ends EX11 and EX21 of which are connected to the two buried zones W11 and W21.

In the embodiment that is just been described, the five electrically conductive paths CH1-CH5 are individualized and are intended each to receive a potential difference between the respective two ends thereof. They are thus connected separately to the detection circuit.

Furthermore, the staircase portions of different electrical paths, on the one hand, and the partial vertical superposition of staircase portions, on the other hand, make it possible to improve the detection of vertical cracks that may be present in these areas of the integrated circuit.

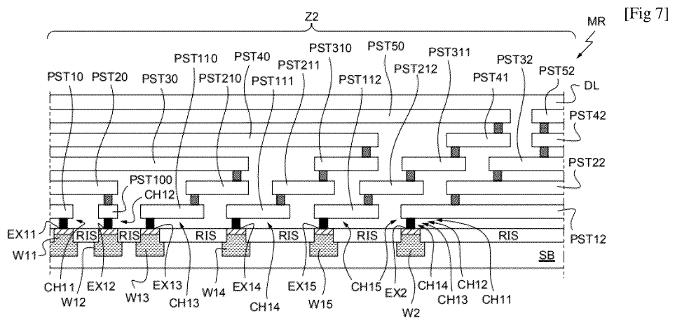

This being the case, it is possible, as illustrated on FIG. 7, to reduce the number of buried zones, and therefore the space requirement on the silicon, by producing five electrically conductive paths connected in a star.

More precisely, in the example of FIG. 7, the integrated circuit includes six semiconductor zones W11-W15 and W2 buried in the substrate SB under the second part Z2 of the wall MR.

All the electrically conductive tracks have an end connected to the zone W2.

### Formation of an Electrically Conductive Path CH15

For forming this path CH15, the wall also includes, at the metal level M5, two metal tracks PST50 and PST52 that respectively extend on each side the alternation of the first and second conductive stacks MD1 and MD2.

The track PST50 is connected to the semiconductor zone W15 by means of the metal tracks PST41, PST311, PST212, PST112 respectively located at the metal levels M4, M3, M2 and M1, and by means of vias and a contact.

The track PST52 is connected to the semiconductor zone W2 by means of the metal tracks PST42, PST32, PST22, PST12 respectively located at the metal levels M4, M3, M2 and M1, and by means of vias and a contact.

The tracks PST15 and PST24 of the conductive stacks MD1 and MD2 form, with the tracks PST50, PST52, PST41, PST311, PST212, PST112, PST42, PST32, PST22, PST12 and the corresponding vias and contacts, the electrically conductive path CH15, the two ends EX15 and EX2 of which are connected to the two buried zones W15 and W2.

Moreover, as can be seen on the figure, this path CH15 includes a first staircase portion formed by the tracks PST41, PST311, PST212 and PST112, and a second staircase portion formed by the tracks PST42, PST32, PST22 and PST12.

Thus, in the first staircase portion, the metal track PST41 is laterally offset, in a horizontal plane, with respect to the adjacent lower track PST311. The metal track PST311 is laterally offset with respect to the adjacent lower track PST212, and the track PST212 is laterally offset with respect to the adjacent lower track PST112. The conductive vias coupling these different tracks are not vertically aligned one to the other. Therefore, if a vertical crack were to appear in a region located between these conductive vias, it could be detected.

Furthermore, in the second staircase portion, the metal track PST32 is laterally offset, in a horizontal plane, with respect to the adjacent upper track PST42. The metal track PST22 is laterally offset with respect to the adjacent upper track PST32, and the track PST12 is laterally offset with respect to the adjacent upper track PST22. The conductive vias coupling these different tracks are not vertically aligned two by two. Therefore, if a vertical crack were to appear in a region located between these conductive vias, it could be detected.

In addition, there is a partial vertical superposition of the first staircase portion PST41/PST311/PST212/PST112 with the second staircase portion PST42/PST32/PST22/PST12. This arrangement, in which two staircase portions are partially vertically superposed, enables the detection of vertical cracks that may be present between these two parts of the electrical paths CH15.

### Formation of an Electrically Conductive Path CH14

For forming this path CH14, the wall also includes, at the metal level M4, two metal tracks PST40 and PST42 that respectively extend on each side the alternation of the first and second conductive stacks MD1 and MD2.

The track PST40 is connected to the semiconductor zone W14 by means of the metal tracks PST310, PST211, PST111, respectively located at the metal levels M3, M2 and M1, and by means of vias and a contact.

The track PST42 is connected to the semiconductor zone W2 by means of the metal tracks PST32, PST22, PST12 respectively located at the metal levels M3, M2 and M1, and by means of vias and a contact.

The tracks PST14 and PST23 of the conductive stacks MD1 and MD2 form, with the tracks PST40, PST42, PST310, PST211, PST111, PST32, PST22, PST12 and the corresponding vias and contacts, the electrically conductive path CH14, the two ends EX14 and EX2 of which are connected to the two buried zones W14 and W2.

Moreover, as can be seen on the figure, this path CH14 includes a first staircase portion formed by the tracks PST310, PST211 and PST111, and a second staircase portion formed by the tracks PST42, PST32, PST22 and PST12.

Thus, in the first staircase portion, the metal track PST310 is laterally offset, in a horizontal plane, with respect to the adjacent lower track PST211. The metal track PST211 is laterally offset with respect to the adjacent lower track PST111. The conductive vias coupling these different tracks are not vertically aligned two by two. Therefore, if a vertical crack were to appear in a region located between these conductive vias, it could be detected.

In addition, there is a partial vertical superposition of the staircase portion PST41/PST311/PST212/PST112 with the staircase portion PST310/PST211/PST111. This arrangement, in which two staircase portions are partially vertically superposed, enables the detection of vertical cracks that may be present between these parts of the electrical paths CH15 and CH14.

### Formation of an Electrically Conductive Path CH13

For forming this path CH13, the wall also includes, at the metal level M3, two metal tracks PST30 and PST32 that respectively extend on each side the alternation of the first and second conductive stacks MD1 and MD2.

The track PST30 is connected to the semiconductor zone W13 by means of the metal tracks PST210, PST110 respectively located at the metal levels M2 and M1, and by means of vias and a contact.

The track PST32 is connected to the semiconductor zone W2 by means of the metal tracks PST22, PST12 respectively located at the metal levels M2 and M1, and by means of vias and a contact.

The tracks PST13 and PST22 of the conductive stacks MD1 and MD2 form, with the tracks PST30, PST32, PST210, PST110, PST22, PST12 and the corresponding vias and contacts, the electrically conductive path CH13, the two ends EX13 and EX2 of which are connected to the two buried zones W13 and W2.

Moreover, as can be seen on the figure, this path CH13 includes a first staircase portion formed by the tracks PST210 and PST110, and a second staircase portion formed by the tracks PST32, PST22 and PST12.

Thus, in the first staircase portion, the metal track PST210 is laterally offset, in a horizontal plane, with respect to the adjacent lower track PST110. The conductive vias coupling these different tracks are not vertically aligned two by two. Therefore, if a vertical crack were to appear in a region located between these conductive vias, it could be detected.

In addition, there is a partial vertical superposition of the staircase portion PST210/PST110 with the staircase portion PST310/PST211/PST111. This arrangement, in which two staircase portions are partially vertically superposed, enables the detection of vertical cracks that may be present between these parts of the electrical paths CH14 and CH13.

### Formation of an Electrically Conductive Path CH12

For forming this path CH12, the wall also includes, at the metal level M2, two metal tracks PST20 and PST22 that respectively extend on each side the alternation of the first and second conductive stacks MD1 and MD2.

The track PST20 is connected to the semiconductor zone W12 by means of the metal track PST100 located at the metal level M1, and by means of a via and a contact.

The track PST22 is connected to the semiconductor zone W2 by means of the metal track PST12 located at the metal level M1, and by means of a via and a contact.

The tracks PST12 and PST21 of the conductive stacks MD1 and MD2 form, with the tracks PST20, PST22, PST12 and the corresponding vias and contacts, the electrically conductive path CH12, the two ends EX12 and EX2 of which are connected to the two buried zones W12 and W2.

Moreover, as can be seen on the figure, this path CH12 includes a staircase portion formed by the tracks PST22 and PST12.

### Formation of an Electrically Conductive Path CH11

For forming this path CH11, the wall also includes, at the metal level M1, two metal tracks PST10 and PST12 that respectively extend on each side the alternation of the first and second conductive stacks MD1 and MD2.

The track PST10 is connected to the semiconductor zone W11 by means of a contact.

The track PST12 is connected to the semiconductor zone W2 by means of a contact.

The tracks PST11 and the semiconductor layer CS of the conductive stacks MD1 and MD2 form, with the tracks PST10, PST12 and the corresponding vias and contacts, the electrically conductive path CH11, the two ends EX11 and EX2 of which are connected to the two buried zones W11 and W2.

In the embodiment that has just been described, the five electrically conductive paths CH11-CH15 are connected in parallel. A reference voltage, for example earth, can be applied to the zone W2 and therefore to the common end of the five paths CH11-CH15, and an individualized voltage, for example 3 volts, can be applied to each other end of the paths.

Furthermore, the staircase portions of different electrical paths, on the one hand, and the partial vertical superposition of staircase portions, on the other hand, make it possible to improve the detection of vertical cracks that may be present in these areas of the integrated circuit.

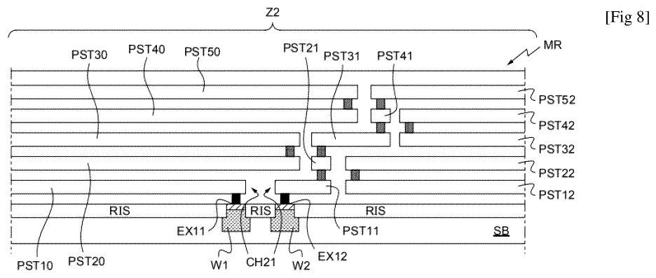

This being the case, it is possible, as illustrated on FIG. 8, to reduce further the number of buried zones, and therefore the space requirement on the silicon, by producing a single electrically conductive path CH21 with all the tracks, layer CS, vias and contacts of the wall MR.

More precisely, in the example of FIG. 8, the integrated circuit includes two semiconductor zones W1 and W2 buried in the substrate SB under the second part Z2 of the wall MR.

The wall includes, in its second part Z2, a metal track PST10 at the metal level M1, connected to the zone W1 by contact.

The end EX11 of the contact forms a first end of the path CH21.

The metal track is extended by the tracks of the conductive stacks MD1 and MD2 to join the track PST12.

The track PST12 is connected by a via to the track PST22, located at the metal level M2, which is extended by the tracks of the conductive stacks MD1 and MD2 to join the track PST20.

The track PST20 is connected by a via to the track PST30, located at the metal level M3, which is extended by the tracks of the conductive stacks MD1 and MD2 to join the track PST32.

The track PST32 is connected by a via to the track PST42, located at the metal level M4, which is extended by the tracks of the conductive stacks MD1 and MD2 to join the track PST40.

The track PST40 is connected by a via to the track PST50, located at the metal level M5, which is extended by the tracks of the conductive stacks MD1 and MD2 to join the track PST52.

The track PST52 is connected to the buried zone W2 by means of the tracks PST41, PST31, PST21, PST11 (respectively located at the metal levels M4, M3, M2 and M1), and by means of vias and a contact the end EX12 of which forms a second end of the path CH21.

Moreover, the tracks PST41, PST31, PST21 and PST11 form a staircase portion of the path CH21.

Indeed, the metal track PST31 is laterally offset, in a horizontal plane, with respect to the adjacent upper track PST41, on the one hand, and with respect to the adjacent lower track PST21, on the other hand. The conductive vias coupling these adjacent tracks are not vertically aligned, that is, they are not located directly above one another. Therefore, if a vertical crack were to appear in a region located between these conductive vias, it could be detected.

In addition, the metal track PST11 is laterally offset, in a horizontal plane, with respect to the adjacent upper track PST21. The conductive vias coupling this track PST11 to, on the one hand, the well W2, and on the other hand, the adjacent upper track PST21, are not vertically aligned. Therefore, if a vertical crack were to appear in a region located between these conductive vias, it could be detected.

Furthermore, the track PST31 of the staircase portion PST41/PST31/PST21 is partially vertically superposed with the adjacent upper track PST40 and the adjacent lower track PST22. Similarly, the track PST11 of the staircase portion PST21/PST11 is partially vertically superposed with the adjacent upper track PST20. This arrangement, in which a staircase portion is partially vertically superposed with tracks of adjacent levels, enables the detection of vertical cracks that may be present between these parts of electrical paths.

Whatever the embodiment, the conductive stacks with a trapezoidal longitudinal section, the staircase portion or portions, and the vias and contacts guarantee good detection of an electrical interruption of the electrically conductive path or paths by vertical cracks and/or horizontal cracks (delamination) appearing in the wall.

This is because the detectability of defects is greatly improved by a wide filling of the wall with metal and a reduction in the dielectric regions.

The wall is produced by conventional steps used in producing the BEOL part of an integrated circuit, namely in particular steps of etching, deposition of metal, etc.

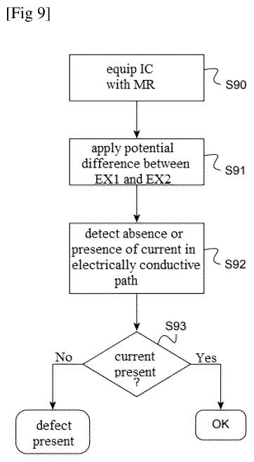

FIG. 9 is now referred to more particularly to describe an implementation of a method for generating defects.

In a step S90, the integrated circuit IC is equipped with a wall MR of the type described above and including for example at least one electrically conductive path.

In a step S91, a potential difference is applied between the two ends EX1 and EX2 of the path.

In a step S92, the absence or presence of a current in the electrically conductive path is detected.

If in the step S93 the presence of a current is detected, this signifies an absence of defect.

If on the contrary an absence of current is detected, this signifies the presence of at least one defect.

What is claimed is:

1. An integrated circuit, comprising
a semiconductor substrate,
an annular wall, located on and at a periphery of the semiconductor substrate, and including in a first part at least one first conductive stack and at least one second conductive stack configured to be mutually electrically connected,
each first conductive stack including a stack of first electrically conductive tracks separated by an electrically insulating material and arranged in a first pattern having a longitudinal section of a trapezoidal type, and
each second conductive stack including a stack of second electrically conductive tracks separated by the electrically insulating material and arranged in a second pattern having a longitudinal section of the trapezoidal type reversed with respect to the first pattern, all the first and second electrically conductive tracks forming together at least one electrically conductive path having, in a second part of the wall, two ends, each end of each electrically conductive path being configured to be electrically connected to a semiconductor zone buried in the substrate under the second part of the wall, at least one electrically conductive path including a staircase portion in the second part of the wall; and
detection circuit configured to be connected to the semiconductor zones and configured to detect at least one type of structural defect in the integrated circuit, by detecting at least one electrical interruption of at least one electrically conductive path of the annular wall.

2. The integrated circuit according to claim 1, wherein the electrically conductive path comprises, in the second part of the wall, metal tracks located on successive metal levels of the integrated circuit, and wherein the staircase portion comprises a metal track of a metal level that is coupled to a metal trace of an adjacent metal level, by at least one conductive via, and wherein the metal track is laterally offset with respect to the adjacent metal track.

3. The integrated circuit according to claim 2, wherein, in the staircase, a metal track of a metal level is coupled to an upper metal track of an adjacent upper metal level by at least one upper conductive via, and is coupled to a lower metal track of an adjacent lower metal level by a lower conductive via; wherein the metal track is laterally offset with respect to the upper metal track and/or the lower metal track; and wherein the upper conductive via and the lower conductive via are laterally offset from each other.

4. The integrated circuit according to claim 2, wherein a metal track of a staircase portion, laterally offset with respect to a metal track of an adjacent metal level to which it is coupled by at least one conductive via, is partially vertically superposed on another metal track of the same adjacent metal level.

5. The integrated circuit according to claim 4, wherein the two metal tracks partially vertically superposed on one another belong to different staircase portions.

6. The integrated circuit according to claim 1, wherein the wall includes, in the first part, an alternation of first conductive stacks and second conductive stacks configured to be mutually electrically connected.

7. The integrated circuit according to claim 1, wherein the first electrically conductive tracks comprise N first metal tracks respectively located on N first metal levels of the integrated circuit, N being greater than or equal to 2, and the second electrically conductive tracks comprise an electrically conductive layer on a top surface of the substrate and N−1 second metal tracks respectively located on N−1 first metal levels.

8. The integrated circuit according to claim 1, wherein all the first and second electrically conductive tracks form together N electrically conductive paths respectively located on N first metal levels of the integrated circuit, and the integrated circuit comprises 2N buried semiconductor zones.

9. The integrated circuit according to claim 1, wherein all the first and second electrically conductive tracks form together N electrically conductive paths respectively located on N first metal levels of the integrated circuit, the N electrically conductive tracks having respectively N first ends respectively connected to N distinct buried semiconductor zones and N second ends all connected to one and the same second buried zone.

10. The integrated circuit according to claim 1, wherein all the first and second electrically conductive tracks form together a single electrically conductive path extending over N first metal levels of the integrated circuit, the two ends of the path being connected to two buried semiconductor zones.

11. The integrated circuit according to claim 1, furthermore comprising a sealing ring located on and at the periphery of the semiconductor substrate and containing the annular wall.

12. The integrated circuit according to claim 1, furthermore comprising a sealing ring located on and at the periphery of the semiconductor substrate and wherein the annular wall bears on one or other of sides of the sealing ring.

13. The integrated circuit according to claim 1, furthermore comprising a sealing ring located on and at the periphery of the semiconductor substrate and two annular walls bearing respectively on two sides of the sealing ring.

14. The integrated circuit according to claim 1, wherein the type of structural defect comprises a crack or a delamination.

15. The integrated circuit according to claim 1, wherein the detection circuit is located in a core of the integrated circuit and is configured to apply the potential difference between the semiconductor zones.

16. The integrated circuit according to claim 1, wherein, in said staircase portion, two adjacent metal tracks that are laterally offset from one another have a mutual overlap region with a length ranging from 1 μm to 10 μm.

17. A method for detecting at least one type of structural defect in an integrated circuit, comprising:
applying a potential difference between two ends of at least one electrically conductive path of an integrated circuit, the integrated circuit comprising an annular wall, located on and at a periphery of a semiconductor substrate, and including in a first part at least one first conductive stack and at least one second conductive stack configured to be mutually electrically connected,
each first conductive stack including a stack of first electrically conductive tracks separated by an electrically insulating material and arranged in a first pattern having a longitudinal section of a trapezoidal type, and
each second conductive stack including a stack of second electrically conductive tracks separated by the electrically insulating material and arranged in a second pattern having a longitudinal section of the trapezoidal type reversed with respect to the first pattern, all the first and second electrically conductive tracks forming together at least one electrically conductive path having, in a second part of the wall, the two ends, each end of each electrically conductive path being configured to be electrically connected to a semiconductor zone buried in the substrate under the second part of the wall, at least one electrically conductive path including a staircase portion in the second part of the wall; and
identify a structural defect in response to determining an absence of current circulating in the at least one electrically conductive path.

18. The method according to claim 17, wherein the type of the structural defect comprises a crack or a delamination.

19. The method according to claim 18, wherein the type of the structural defect comprises a crack and a delamination.

20. The method according to claim 17, further comprising detecting electrical interruptions in multiple electrically conductive paths of the integrated circuit.

21. The method according to claim 17, wherein the first and second conductive stacks are arranged in an alternating pattern in the first part of the annular wall.

22. The method according to claim 17, wherein the potential difference is applied between semiconductor zones buried in the substrate under the second part of the wall.

23. A system for detecting structural defects in an integrated circuit, comprising:
a test circuit configured to apply a potential difference between two ends of at least one electrically conductive path of an integrated circuit; the integrated circuit comprising:
an annular wall located on and at a periphery of a semiconductor substrate, the annular wall including in a first part at least one first conductive stack and at least one second conductive stack mutually electrically connected, each first conductive stack including a stack of first electrically conductive tracks separated by an electrically insulating material and arranged in a first pattern having a longitudinal section of a trapezoidal type, and each second conductive stack including a stack of second electrically conductive tracks separated by the electrically insulating material and arranged in a second pattern having a longitudinal section of the trapezoidal type reversed with respect to the first pattern, and
semiconductor zones buried in the substrate under a second part of the wall and connected to ends of at least one electrically conductive path formed by the first and second electrically conductive tracks; and
a detection circuit configured to:
apply a potential difference between the semiconductor zones connected to the ends of the at least one electrically conductive path, and
detect an absence of current circulating in the at least one electrically conductive path to identify a structural defect in the integrated circuit.

24. The system according to claim 23, wherein the detection circuit is configured to detect electrical interruptions in multiple electrically conductive paths of the integrated circuit.

25. The system according to claim 23, wherein the detection circuit is configured to identify a location of the structural defect based on which electrically conductive path has an electrical interruption.
